(19) United States
(12) Patent Application Publication
(10) Pub. No.: US 2016/0043297 A1
(43) Pub. Date: Feb. 11, 2016

(54) HIGH EFFICIENCY THERMOELECTRIC CONVERSION UNIT

(71) Applicant: HITACHI, LTD., Tokyo (JP)

(72) Inventors: Jun HAYAKAWA, Tokyo (JP); Yosuke KUROSAKI, Tokyo (JP); Akinori NISHIDE, Tokyo (JP)

(21) Appl. No.: 14/780,514

(22) PCT Filed: Mar. 27, 2013
(86) PCT No.: PCT/JP2013/059153

§ 371 Date: Sep. 25, 2015

(51) Int. Cl. H01L 35/32; H01L 25/10; H01L 35/20; H01L 35/04

(52) U.S. Cl. CPC H01L 35/32; H01L 35/04; H01L 25/10; H01L 35/20

(57) ABSTRACT

In order to provide a thermoelectric conversion unit capable of generating power with high thermoelectric conversion efficiency, in the thermoelectric conversion unit including: a plurality of thermoelectric conversion modules (1 to 3) including a plurality of pairs of n-type thermoelectric conversion material portions and p-type thermoelectric conversion material portions connected by electrodes; and a hot water pipe 201 and a cold water pipe 202 for generating a temperature difference in the thermoelectric conversion modules and generating power by using a Seebeck effect, at least one of the plurality of thermoelectric conversion modules is different from another thermoelectric conversion module in at least one of a thickness of the thermoelectric conversion material portions, the kind of thermoelectric conversion material, and a thickness of the electrodes.

### TECHNICAL FIELD

The present invention relates to a thermoelectric conversion unit having high conversion efficiency.

### BACKGROUND ART

A thermoelectric conversion module can convert thermal energy to electric energy and is therefore expected to be a generator capable of generating electricity from unused industrial waste heat, automobile waste heat, hot springs, and the like. A thermoelectric conversion unit is a thermal power generator including a single or a plurality of thermoelectric conversion modules and includes supplemental equipment such as a heat source and a cooling source for generating a temperature difference in the thermoelectric conversion modules and pipes. The thermoelectric conversion unit is disclosed in, for example, PTL 1.

### CITATION LIST

### Patent Literature

PTL 1: JP-A-2010-278460

### SUMMARY OF INVENTION

### Technical Problems

As a result of study, the inventors found that, in a conventional thermoelectric conversion unit, arrangement of thermoelectric conversion modules, a size of a thermoelectric conversion material forming the thermoelectric conversion modules, and the like to maximize an output of the unit under environmental conditions such as temperatures and flow rates of a heat source and a cooling source are not optimized. Therefore, large amounts of heat and electricity are lost.

An object of the invention is to provide a thermoelectric conversion unit capable of generating power with high thermoelectric conversion efficiency even in the case where a temperature of a heat source is changed in the thermoelectric conversion unit and a plurality of thermoelectric conversion modules constituting the thermoelectric conversion unit have different temperature differences between the heat source and a cooling source.

### Solution to Problems

An embodiment to achieve the above object includes:

a plurality of thermoelectric conversion modules including a plurality of pairs of n-type thermoelectric conversion material portions and p-type thermoelectric conversion material portions connected by electrodes for extracting electric power; and

supply means provided in upper and lower surfaces in a thickness direction of the n-type and p-type thermoelectric conversion material portions of the thermoelectric conversion modules, the supply means being for generating a temperature difference in the thermoelectric conversion modules and supplying a heat source and a cooling source for generating power by using a Seebeck effect of the thermoelectric conversion material portions, in which:

the plurality of thermoelectric conversion modules are connected in parallel; and

one of the adjacent thermoelectric conversion modules or at least one of the plurality of thermoelectric conversion modules is different from another thermoelectric conversion module in at least one of a thickness of the thermoelectric conversion material portions, the kind of thermoelectric conversion material, and a thickness of the electrodes.

Further, a thermoelectric conversion unit includes:

a plurality of thermoelectric conversion modules including a plurality of pairs of n-type thermoelectric conversion material portions and p-type thermoelectric conversion material portions connected by electrodes for extracting electric power; and

supply means provided in upper and lower surfaces in a thickness direction of the n-type and p-type thermoelectric conversion material portions of the thermoelectric conversion modules, the supply means being for generating a temperature difference in the thermoelectric conversion modules and supplying a heat source and a cooling source for generating power by using a Seebeck effect of the thermoelectric conversion material portions, in which:

the plurality of thermoelectric conversion modules are connected in parallel;

one of the adjacent thermoelectric conversion modules or at least one of the plurality of thermoelectric conversion modules is different from another thermoelectric conversion module in at least one of a thickness of the thermoelectric conversion material portions, the kind of thermoelectric conversion material, and a thickness of the electrodes;

αₕ=Aₕv

α_{c}=A_{c}v

where Tₕ represents a temperature of the heat source, T_{c} represents a temperature of the cooling source, κ represents thermal conductivity of the thermoelectric conversion material portion, m₀ represents a material property constant of the thermoelectric conversion material portion, αₕ represents a heat transfer coefficient of the heat source, α_{c} represents a heat transfer coefficient of the cooling source, v represents flow velocity of hot water and cold water, and Aₕ and A_{c} represent specific constants of temperature dependence of the heat source and the cooling source represent; and

a thickness t which satisfies

500 W/m²≧[(Tₕ−T_{c})2/{(1/αₕ)+(t/κ)+(1/α_{c})}]×[(m₀−1)/{m₀(Tₕ+273)+(T_{c}+273)}]

is selected as a thickness t of the thermoelectric conversion material portion.

### Advantageous Effects of Invention

According to the invention, it is possible to provide a thermoelectric conversion unit capable of generating power with high thermoelectric conversion efficiency even in the case where a temperature of a heat source is changed in the thermoelectric conversion unit and a plurality of thermoelectric conversion modules constituting the thermoelectric conversion unit have different temperature differences between the heat source and a cooling source.

### BRIEF DESCRIPTION OF DRAWINGS

FIG. 1 is schematic diagrams illustrating a configuration example of thermoelectric conversion modules included in a thermoelectric conversion unit according to Example 1 of the invention, and a view in an upper central part is a top view, a view in a central part is a cross-sectional view taken along the line A′B′, a view in a lower central part is a bottom view, a right view is a cross-sectional view taken along the line C′D′, and a left view is a cross-sectional view taken along the line E′F′.

FIG. 2 is schematic diagrams illustrating another configuration example of the thermoelectric conversion modules included in the thermoelectric conversion unit according to Example 1 of the invention, and a view in an upper central part is a top view, a view in a central part is a cross-sectional view taken along the line A′B′, a view in a lower central part is a bottom view, a right view is a cross-sectional view taken along the line C′D′, and a left view is a cross-sectional view taken along the line E′F′.

FIG. 3 is schematic diagrams illustrating another configuration example of the thermoelectric conversion modules included in the thermoelectric conversion unit according to Example 1 of the invention, and a view in an upper central part is a top view, a view in a central part is a cross-sectional view taken along the line A′B′, a view in a lower central part is a bottom view, a right view is a cross-sectional view taken along the line C′D′, and a left view is a cross-sectional view taken along the line E′F′.

FIG. 4 is schematic diagrams illustrating a configuration example of the thermoelectric conversion unit according to Example 1 of the invention, and an upper right view is a front view, a lower right view is a top view, and a left view is a side view.

FIG. 5 is schematic diagrams illustrating another configuration example of the thermoelectric conversion unit according to Example 1 of the invention, and an upper right view is a top view, a lower right view is a cross-sectional view taken along the line A′B′, and a left view is a cross-sectional view taken along the line C′D′.

FIG. 6 is schematic diagrams illustrating a configuration example of a thermoelectric conversion unit according to Example 2 of the invention, and an upper right view is a top view, a lower right view is a cross-sectional view taken along the line A′B′, and a left view is a cross-sectional view taken along the line C′D′.

FIG. 7 is schematic diagrams illustrating another configuration example of the thermoelectric conversion unit according to Example 2 of the invention, and an upper right view is a top view, a lower right view is a cross-sectional view taken along the line A′B′, and a left view is a cross-sectional view taken along the line C′D′.

FIG. 8 is schematic diagrams illustrating a configuration example of a thermoelectric conversion unit according to Example 3 of the invention, and an upper right view is a top view, a lower right view is a cross-sectional view taken along the line A′B′, and a left view is a cross-sectional view taken along the line C′D′.

FIG. 9 is schematic diagrams illustrating another configuration example of the thermoelectric conversion unit according to Example 3 of the invention, and an upper right view is a top view, a lower right view is a cross-sectional view taken along the line A′B′, and a left view is a cross-sectional view taken along the line C′D′.

FIG. 10 (a) is schematic diagrams illustrating a configuration example of a thermoelectric conversion unit of the invention, and an upper right view is a front view, a lower right view is a top view, and a left view is a side view, and (b) is a production flowchart of the thermoelectric conversion unit of the invention.

FIG. 11 is data showing dependence of output density on a thickness of a thermoelectric conversion material, which is obtained when a temperature of a heat source in the thermoelectric conversion unit of the invention is changed, and (a) shows a case where thermal conductivity of the thermoelectric conversion material is 10 W/mK, (b) shows a case where the thermal conductivity of the thermoelectric conversion material is 5 W/mK, (c) shows a case where the thermal conductivity of the thermoelectric conversion material is 2.5 W/mK, (d) shows a case where the thermal conductivity of the thermoelectric conversion material is 1 W/mK, (e) shows a case where the thermal conductivity of the thermoelectric conversion material is 0.5 W/mK, and (f) shows a case where the thermal conductivity of the thermoelectric conversion material is 0.1 W/mK.

FIG. 12 is a schematic diagram illustrating a ratio of a height of the thermoelectric conversion material to a height of an upper electrode to a height of a lower electrode, which is obtained when thermoelectric conversion modules have a uniform height in the thermoelectric conversion unit of the invention, and (a) illustrates a case where the thermoelectric conversion material is high, (b) illustrates a case where the height of the thermoelectric conversion material is decreased and the height of the upper electrode is increased by that amount, (c) shows a case where the height of the thermoelectric conversion material is decreased and the height of the lower electrode is increased by that amount, and (d) shows a case where the height of the thermoelectric conversion material is decreased and the height of the upper electrode and the height of the lower electrode are equally increased by that amount.

### DESCRIPTION OF EMBODIMENTS

In a thermoelectric conversion unit including a plurality of thermoelectric conversion modules which have the same structure, the inventors increased a length of a liquid medium pipe in order to effectively use a temperature of a heat source for power generation. As a result, the inventors found that, for example, a liquid medium had 90° C. in an inlet port of the pipe but was decreased to be about 40° C. in an outlet port of the pipe, i.e., a temperature difference between the heat source and a cooling source became small as a distance from the inlet port was increased, and, in the case where such reduction of the temperature difference occurred, the thermoelectric conversion modules having the same structure could not always obtain high thermoelectric conversion efficiency in respective temperature differences. The invention is based on this new knowledge and is configured so that the thermoelectric conversion modules having the respective temperature differences have equal thermoelectric conversion efficiency in the thermoelectric conversion unit. Specifically, each thermoelectric conversion module contains a thermoelectric conversion material having a different thickness.

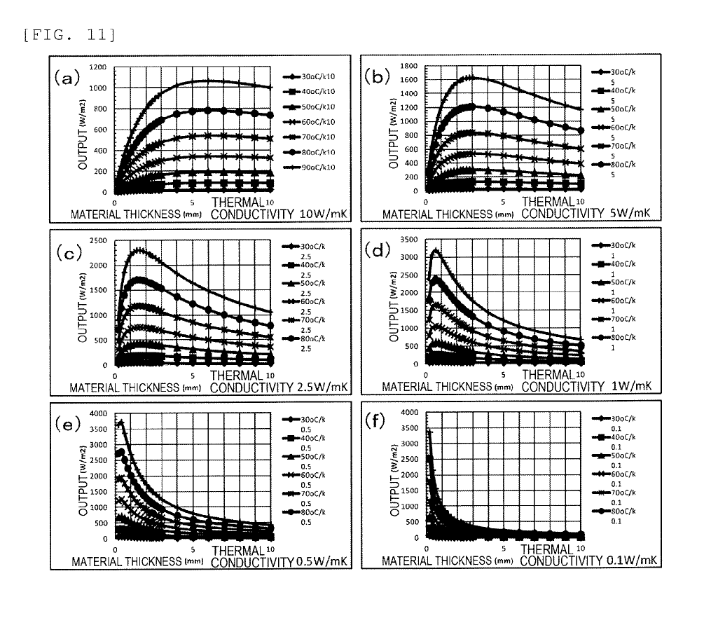

In order to obtain the largest output in the thermoelectric conversion unit, a method of selecting sizes of individual thermoelectric conversion modules 1 to 3 (M1, M2, M3, . . . , Mn−1, Mn) constituting the thermoelectric conversion unit will be described with reference to FIG. 10(a). FIG. 10(a) illustrates a thermoelectric conversion unit, and an upper right view is a plan view, a lower right view is a cross-sectional view taken along the line A′B′, and a left view is a cross-sectional view taken along the line C′D′. A reference sign 201 indicates a hot water pipe through which hot water flows, which serves as a heat source, a reference sign 202 indicates a cold water pipe through which cold water flows, which serves as a cooling source, a reference sign 301 indicates a thermal insulation member, a black arrow indicates a direction in which hot water flows, and a gray arrow indicates a direction in which cold water flows. In the thermoelectric conversion unit in the lower right view of FIG. 10(a), the thermoelectric conversion module M₁ is provided at a position which is the closest to an input port of hot water and an outlet port of cold water, and therefore the largest temperature difference is generated in the thermoelectric conversion module in the thermoelectric conversion unit. Further, because a temperature of hot water is decreased in the direction in which hot water flows, the temperature difference generated in the thermoelectric conversion modules becomes small in the direction. Therefore, output of the thermoelectric conversion modules is decreased in the direction in which hot water flows. Furthermore, a quantity of heat, which is determined based on thermal conductivity of the thermoelectric conversion modules, flows in a temperature difference direction of the modules through the thermoelectric conversion modules interposed between the hot water pipe and the cold water pipe, and the quantity thereof is increased as the thermal conductivity of the thermoelectric conversion module is increased. Meanwhile, the temperature difference becomes small when the thermal conductivity becomes large, and there is an optimal size to achieve output of the thermoelectric conversion module which is determined based on the temperature difference and the quantity of heat. A method of determining a thickness t of the thermoelectric conversion material as the optimal size will be described.

The largest output density Q (W/m²) of the thermoelectric conversion module can be expressed by the following expression:

Q=ηₘₐₓ×H (1)

where ηₘₐₓ represents the largest conversion efficiency of the thermoelectric conversion material and H (W/m²) represents a quantity of heat passing through the thermoelectric conversion module.

Herein, the largest conversion efficiency ηₘₐₓ is expressed by the following expression.

ηₘₐₓ=(ΔT/Tₕ)(m₀−1)/[m₀+(T_{c}/Tₕ)] (2)

ΔT/Tₕ=η_{c}, ΔT (temperature difference)=Tₕ−T_{c} (Tₕ: temperature on high-temperature side, T_{c}: temperature on low-temperature side), m₀=(1+ZT)^{1/2}

Herein, ZT indicates a dimensionless performance index of the thermoelectric conversion material and can be expressed by the following expression:

Z=S²/ρκ

where S represents a Seebeck coefficient, ρ represents specific electrical resistance, and κ represents thermal conductivity.

Meanwhile, a heat flow H in a structure of the invention can be expressed by the following expression:

H=1/[(1/αₕ)+(t/κ)+(1/α_{c})] (3)

where αₕ represents a heat transfer coefficient of the heat source (hot water), α_{c} represents a heat transfer coefficient of the cooling source (cold water), and v represents flow velocity of hot water/cold water. Herein, αₕ=Aₕv and α_{c}=A_{c}v, and Ah and Ac indicate specific constants dependent on temperatures of hot water and cold water, respectively.

By substituting an expression (2) and an expression (3) for an expression (1),

the output density Q (W/m²) of a single thermoelectric conversion module obtains

Q=[(Tₕ−T_{c})²/{(1/αₕ)+(t/κ)+(1/α_{c})}]×[(m₀−1)/{m₀(Tₕ+273)+(T_{c}+273)}] (4).

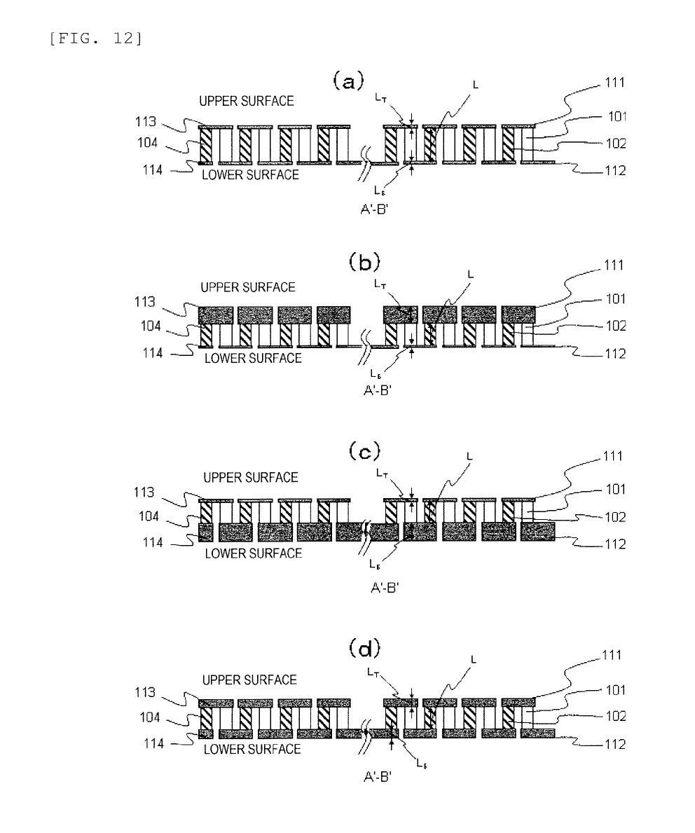

FIG. 11 shows graphs obtained by selecting representative parameters on the basis of the expression (4) and plotting output of the thermoelectric conversion module with respect to the thickness t of the thermoelectric conversion material. In particular, FIG. 11(a) is a view obtained by plotting, with respect to the thickness t of the thermoelectric conversion material forming the thermoelectric conversion module, output density which is obtained in the thermoelectric conversion module having the thermal conductivity of 10 W/mK when a temperature of the heat source is changed from 90° C. to 30° C. under the condition that a flow rate is 20 L/min, flow velocity is 1.5 m, and a temperature of the cooling source is 20° C. As is clear from FIG. 11(a), the thermoelectric conversion material has a thickness which maximizes the output of the thermoelectric conversion module. For example, it is found that, in order to obtain output of a thermal power generation amount of 500 W/m² which is necessary to collect industrial waste heat, the thickness of 1 mm or more is needed in the case where the heat source has 90° C. Further, when the temperature of the heat source is decreased, a lower limit value of the thickness of the thermoelectric conversion module becomes large. Furthermore, it is found that, in the case where the heat source has 60° C. or less, 500 W/m² cannot be obtained regardless of the thickness. In the case where the heat source having 90° C. is used, the thickness needs to be set to 1 mm or more. In the case where the heat source having 80° C. is used, the thickness needs to be set to 1.5 mm or more. In the case where the heat source having 70° C. is used, the thickness needs to be set to 3.5 to 10 mm. Therefore, in the thermoelectric conversion unit of FIG. 10(a), the thickness of the thermoelectric conversion material of the thermoelectric conversion module to be applied is desirably changed in accordance with the direction in which hot water flows. The thickness of the thermoelectric conversion material to be applied is determined based on the temperatures of the heat source and the cooling source at a position of the thermoelectric conversion module containing the above material and thermal conductivity of the above material. The above description is a case where the thermal conductivity is 10 W/mK. In the case where the thermoelectric conversion module having the thermal conductivity of 5 W/mK is applied, as illustrated in FIG. 11 (b), the thermoelectric conversion material having the thickness of 0.5 mm or more is used in the case where the thermoelectric conversion module is provided at a position of the hot water heat source having 90° C., the thermoelectric conversion material having the thickness of 0.5 mm or more is used in the case of 80° C., the thermoelectric conversion material having the thickness of 0.7 mm or more is used in the case of 70° C., and the thermoelectric conversion material having the thickness of 2 mm to 5 mm is used in the case of 60° C. FIGS. 11(c), (d), (e), and (f) illustrate cases where the thermal conductivity is 2.5 W/mK, 1 W/mK, 0.5 W/mK, and 0.1 W/mK, respectively. In the invention, a Heusler alloy group (described below) is used as the thermoelectric conversion material, and this substance group has a feature in which thermal conductivity thereof falls within a range of 1 to 10 W/mK. The thickness of the above thermoelectric conversion module is determined based on the temperature of the hot water heat source provided in a part in the thermoelectric conversion unit where the thermoelectric conversion module is used, the thermal conductivity of the thermoelectric conversion material to be used therein, and the flow rates/flow velocity of hot water and cold water.

In the thermoelectric conversion unit to be used for collecting waste heat, it is desirable to obtain output of 500 W/m² or more, and, in the case where the temperatures and the flow velocity of hot water/cold water are determined in the expression (4), it is possible to select the thickness t of the thermoelectric conversion material so as to satisfy the following expression.

500≧[(Tₕ−T_{c})²/{(1/αₕ)+(t/κ)+(1/α_{c})}]×[(m₀−1)/{m₀(Tₕ+273)+(T_{c}+273)}]

As described above, in the case where the thickness of the thermoelectric conversion material to be used for the thermoelectric conversion module is changed in the same thermoelectric conversion unit in accordance with an environment thereof, the thickness of the thermoelectric conversion module is also changed. In the case where the thermoelectric conversion modules having different thicknesses are arranged in parallel, the hot water pipe and the cold water pipe do not have a uniform shape in terms of a thickness or the like and have a complicated structure. Therefore, hot water and cold water in the pipes do not flow uniformly, which results in reduction of output of the thermoelectric conversion modules and the thermoelectric conversion unit. Thus, it is preferable that the thermoelectric conversion modules have the substantially uniform thickness even in the case where the thickness of the thermoelectric conversion material is changed.

FIG. 12 illustrates a method of causing the thermoelectric conversion modules to have the substantially uniform thickness. A reference sign 101 indicates a p-type thermoelectric conversion material, reference signs 102 and 104 indicate an n-type thermoelectric conversion material, reference signs 111 and 113 indicate upper electrodes, and reference signs 112 and 114 indicate lower electrodes. As illustrated in FIG. 12(a), a height of the thermoelectric conversion module is defined as L_{M}=L+L_{T}+L_{B}. L indicates a height of the thermoelectric conversion material, L_{T} indicates a thickness of the upper electrode, and L_{B} indicates a thickness of the lower electrode. In the case where the height L of the thermoelectric conversion material is changed, one of L_{T} and L_{B} can be changed so as to achieve uniform L_{M} as illustrated in FIGS. 12(b) and (c). As illustrated in FIG. 12(d), it is also possible to apply a method of achieving uniform L_{M} by changing L_{T} and L_{B} by the same amount in order that the thermoelectric conversion modules in the thermoelectric conversion unit have the substantially uniform thickness. The electrodes to be used are desirably made of a material having large thermal conductivity and small electric resistance, such as copper or aluminum, but may be made of an intermetallic compound containing elements such as Ni, Au, and Mo to increase bond strength.

By changing the height of the thermoelectric conversion material, it is possible to obtain a thermoelectric conversion unit capable of generating power with high conversion efficiency. Further, in the case where the height of the thermoelectric conversion material is changed, the thicknesses of the upper electrodes and the lower electrodes are adjusted so that the thermoelectric conversion modules have the uniform height. With this, it is possible to obtain a thermoelectric conversion unit having a simple structure.

Examples of the invention will be described below with reference to the drawings.

### Example 1

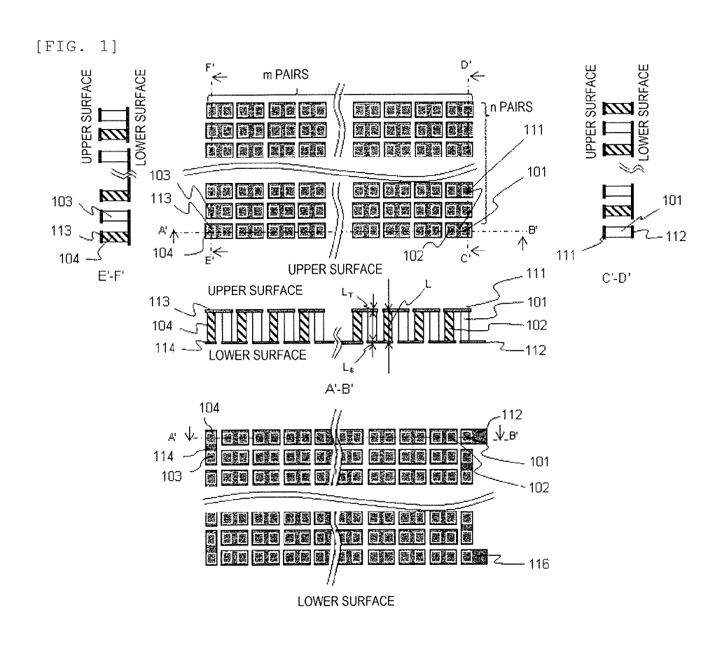

FIG. 1 is schematic diagrams illustrating a configuration example of a thermoelectric conversion modules included in a thermoelectric conversion unit according to Example 1 of the invention. A view in an upper central part of FIG. 1 is a top view, a view in a central part of FIG. 1 is a cross-sectional view taken along the line A′-B′, a view in a lower central part of FIG. 1 is a bottom view, a right view of FIG. 1 is a cross-sectional view taken along the line C′-D′, and a left view of FIG. 1 is a cross-sectional view taken along the line E′-F′. Note that the same reference signs indicate the same components. This thermoelectric conversion module includes a plurality of pairs of, i.e., m pairs×n pairs of p-type thermoelectric conversion material portions (101 and 103) and n-type thermoelectric conversion material portions (102 and 104) and electrodes (111, 112, 113, and 114) connecting them. Herein, a thickness of each thermoelectric conversion material portion is defined as L, thicknesses of the electrodes are defined as L_{T} (upper part) and L_{B} (lower part). Those parameters are determined based on thermal conductivity κ of the thermoelectric conversion material portion to be used and an environment (temperature, flow rate, flow velocity, and the like) of a heat source and a cooling source so as to optimize output of the thermoelectric conversion modules. In the case where a temperature T_{H} is generated in an upper part (electrode 111 side) of the thermoelectric conversion modules of this example, a temperature T_{L} is generated in a lower part (electrode 112 side) thereof, and a temperature difference gradient ΔT (=T_{H}−T_{L}) is applied in a thickness direction (direction of thickness L) of the thermoelectric conversion material portions of this example, electricity generated by a Seebeck effect in a Heusler alloy portion is extracted from the electrodes as electric power (voltage or current). For example, in the case of the thermoelectric conversion modules of this example, electric power is obtained by providing, between the electrode 112 and the electrode 116 (see the view in the lower central part of FIG. 1), a load resistor having a resistance value which is equal to that of an electric resistor therebetween.

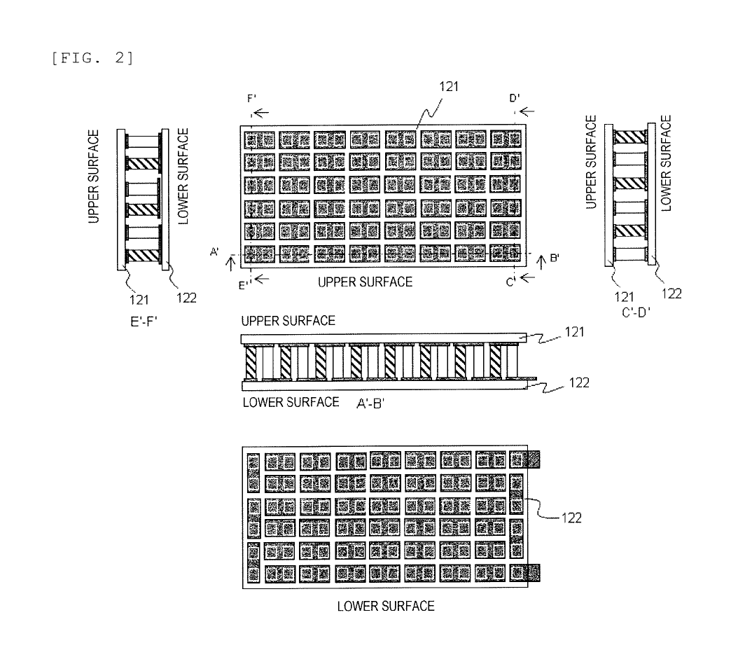

FIG. 2 is schematic diagrams illustrating a configuration example of thermoelectric conversion modules 2 including high thermal conductivity insulation members (121 and 122) on upper and lower surfaces of the thermoelectric conversion modules illustrated in FIG. 1 in order to suppress electrical short circuit between the thermoelectric conversion modules and the heat source and the cooling source which are in contact with the thermoelectric conversion modules. A view in an upper central part of FIG. 2 is a top view, a view in a central part of FIG. 2 is a cross-sectional view taken along the line A′-B′, a view in a lower central part of FIG. 2 is a bottom view, a right view of FIG. 2 is a cross-sectional view taken along the line C′-D′, and a left view of FIG. 2 is a cross-sectional view taken along the line E′-F′. Because the thermoelectric conversion modules 2 include high thermal conductivity insulation member such as alumina or silicon oxide, a current or a voltage generated by a temperature difference generated in the thermoelectric conversion modules is not short-circuited with the heat source and the cooling source which are in contact with the thermoelectric conversion modules. Therefore, it is possible to obtain electric power without any loss. Further, because the material having high thermal conductivity is used, it is possible to transfer heat from the heat source and the cooling source to the thermoelectric conversion modules with a small loss, and it is possible to improve power generation efficiency of the thermoelectric conversion modules.

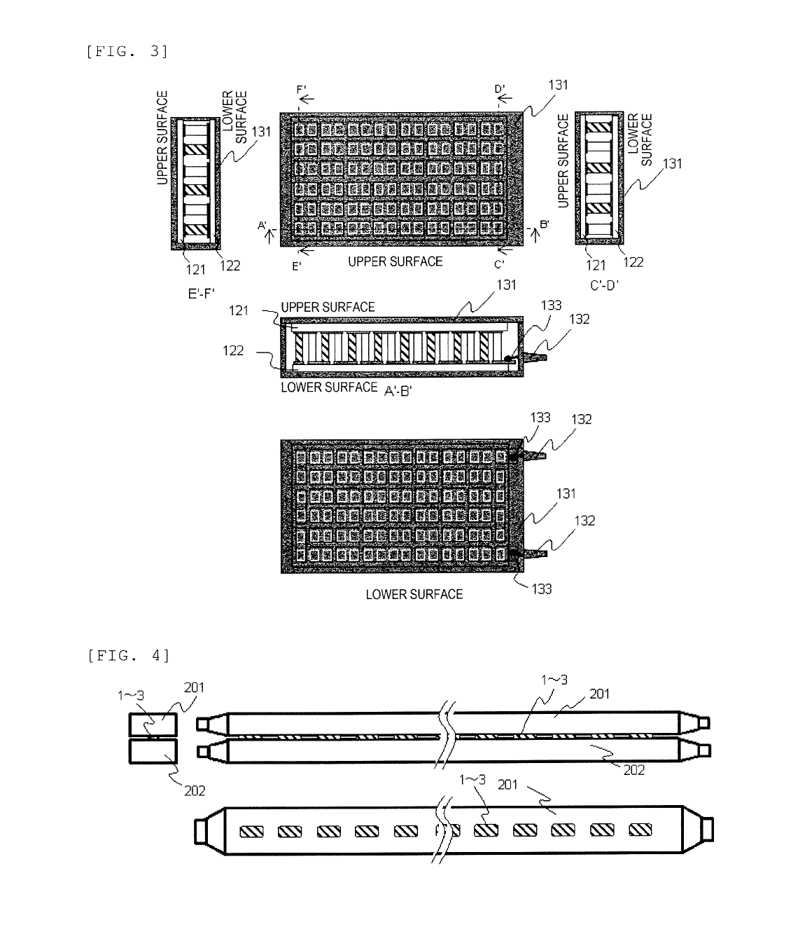

FIG. 3 is schematic diagrams illustrating a configuration example of thermoelectric conversion modules 3 obtained by enclosing the thermoelectric conversion modules 2 illustrated in FIG. 2 with a vacuum package 131. A view in an upper central part of FIG. 3 is a top view, a view in a central part of FIG. 3 is a cross-sectional view taken along the line A′-B′, a view in a lower central part of FIG. 3 is a bottom view, a right view of FIG. 3 is a cross-sectional view taken along the line C′-D′, and a left view of FIG. 3 is a cross-sectional view taken along the line E′-F′. Because the high thermal conductivity insulation member is in contact with the package, heat of the heat source and the cooling source which are in contact with a surface of the package can be efficiently transferred to the modules. Further, because the thermoelectric conversion modules are enclosed with the vacuum package, thermal diffusion to the atmosphere, which is caused by radiant heat, is suppressed, and therefore it is possible to effectively input and output thermal energy to/from the thermoelectric conversion modules. Although SUS and copper are used as the package material in this example, another material having large thermal conductivity and excellent thermal resistance may be used. Further, it is desirable that sealing be performed so that a degree of vacuum in the package is 10⁻⁴ Pa or less. Note that a reference sign 132 indicates a thermoelectric conversion module end electrode and a reference sign 133 indicates an extraction electrode.

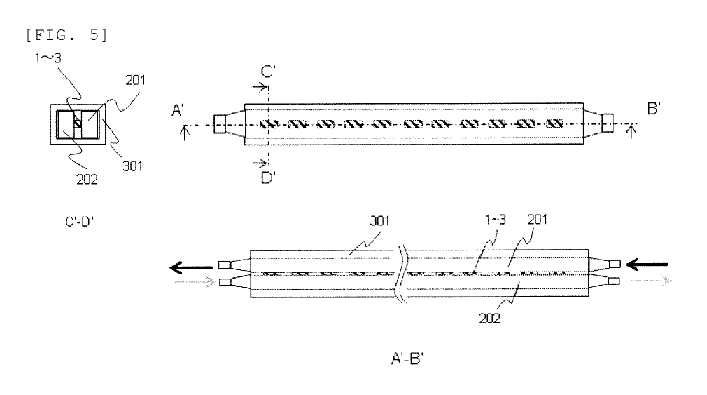

FIG. 4 illustrates a configuration example of a thermoelectric conversion unit in which the thermoelectric conversion modules (1 to 3) illustrated in FIGS. 1 to 3 are adjacent to the heat source and the cooling source. An upper right view of FIG. 4 is a front view, a lower right view of FIG. 4 is a top view, and a left view of FIG. 4 is a side view. In this example, a pair of pipes through which hot water and cold water are supplied is applied (as the heat source and the cooling source). 201 indicates a hot water pipe and 202 indicates a cold water pipe, and the plurality of thermoelectric conversion modules (1 to 3) are arranged in parallel therebetween. The hot water pipe and the cold water pipe are arranged so that hot water and cold water flow in a substantially parallel direction, and the thermoelectric conversion modules are arranged in a direction in which hot water and cold water flow. The thermoelectric conversion modules (1 to 3) are interposed between the hot water pipe 201 and the cold water pipe 202 and a temperature difference is generated in a vertical direction of the thermoelectric conversion modules (1 to 3), and therefore the individual thermoelectric conversion modules generate power. Power generation output of the thermoelectric conversion unit is determined based on the number of thermoelectric conversion modules.

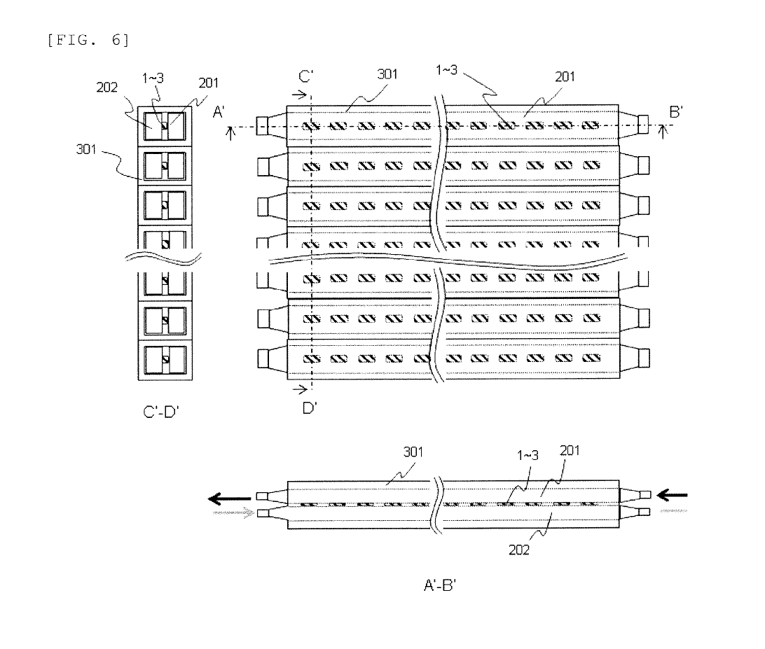

FIG. 5 illustrates a configuration example of a thermoelectric conversion unit having a structure in which the thermoelectric conversion unit illustrated in FIG. 4 is covered with a thermal insulation member 301. An upper right view of FIG. 5 is a front view, a lower right view of FIG. 5 is a top view, and a left view of FIG. 5 is a side view. By applying the thermal insulation member 301, thermal diffusion to the atmosphere from the hot water pipe 201 and the cold water pipe 202 is suppressed, and therefore it is possible to achieve a stable heat source and a stable cooling source.

The thermoelectric conversion material forming the thermoelectric conversion modules and the thermoelectric conversion unit will be described. The following materials are typical examples thereof:

compound semiconductors made of Bi—Te based, Pb—Te based, Si—Ge, and Mg—Si based compounds;
(2) oxide materials such as NaₓCoO₂ (0.3≦x≦0.8) and (ZnO)mIn₂O₃ (1≦m≦19) based materials;
(3) skutterudite compounds such as Zn—Sb based, Co—Sb based, and Fe—Sb based compounds; and
(4) Heusler alloys containing intermetallic compounds such as Fe₂VAl and ZrNiSn.

In such material groups, a dimensionless performance index ZT (T is temperature) which influences output of the thermoelectric conversion modules and the thermoelectric conversion unit is about 1 at most. However, it is expected to improve performance thereof by using a material which is excellent in terms of an environment and a resource such as harmlessness and low costs.

The thermoelectric conversion material to be used for the thermoelectric conversion unit of this example is a full Heusler alloy, and it is possible to apply a material expressed by Fe₂XY. Elements X and Y are selected to increase the performance index ZT. Specifically, it is desirable to select elements shown in Table 1.

TABLE 1

| | Element X | Element Y |
|---|---|---|
| Fe | Ti | Si, Ge, Sn |
| | Zr | |
| | Hf | |
| | V | Al, Ga, In |
| | Nb | |
| | Ta | |
| | Cr | Zn, Cd, Hg, Mg, Ca, Sr, Ba |
| | Mo | |
| | W | |
| | Sc | P, As, Sb, Bi |
| | Y | |

Each elemental composition may be slightly larger or smaller than Fe₂XY. Specifically, Fe falls within the range of 2±0.3, X falls within the range of 1±0.2, and Y falls within the range of 1±0.2, and therefore the sum total of all values of the composition (atomic weight) ratio is 4. This makes it possible to maximize the Seebeck coefficient and obtain a high ZT. As to the element X and the element Y, it is possible to select two or more kinds of elements from the elements shown in Table 1. For example, TiV can be selected as the element X and AlSi can be selected as the element Y, and therefore a Heusler alloy containing five elements such as Fe₂(TiV) (AlSi) can be selected.

Herein, an example where Fe₂TiSn which can achieve a high ZT is used as the thermoelectric conversion material will be described. Production processes of this material will be described. An appropriate composition amount of powder of Fe, Ti, Sn, or an intermetallic compound made of at least one element thereof is weighed and the powder is alloyed with a mechanical alloying method. Herein, mechanical alloying is implemented until a crystal grain size of the powder becomes 1 μm or less. Phonon scattering in a grain boundary is increased as the crystal grain size is decreased, and therefore it is possible to reduce the thermal conductivity, thereby improving the ZT. Mechanical alloying is implemented for several hours to several hundred hours in some cases. The fine powder produced as described above is formed into a sintered body in a high-speed sintering furnace. For example, mechanical alloying is implemented under the condition that 1000° C. is maintained for 10 minutes and rapid cooling is performed to prevent promotion of growth of the crystal grain size. A sintered material having a grain size of 1 μm or less is applied by controlling a temperature, a maintaining time, a heating time, and a cooling time. Further, an amorphous material can be produced by condition control and can be applied to a thermoelectric conversion element. By forming a fine crystal grain or amorphous material having 1 μm or less, thermal conductivity caused by lattice vibration is prevented by the phonon scattering in the grain boundary, and therefore it is possible to reduce thermal conductivity of an Fe₂TiSn based material. The thermal conductivity thereof is reduced to about 1/10, as compared to thermal conductivity of a material having several tens micron order. Fe₂TiSn amorphous can achieve thermal conductivity of 2 W/m·K. A Seebeck coefficient of such an FeTiSn material is 200 μV/K, and specific electrical resistance thereof is about 1.5 μΩm, and therefore ZT>1 can be achieved. Further, by substituting Si for Sn, the Seebeck coefficient can be 200 μV/K at most, and therefore ZT>2 can be achieved. By applying this material to the thermoelectric conversion unit of the invention, it is possible to stably obtain output of 1 kW/m² or more in the case where hot water having less than 100° C. and cold water having 20° C. are introduced.

An example of production steps of the thermoelectric conversion unit according to this example will be described with reference to FIG. 10(b). A thermoelectric conversion material having a desired characteristic is synthesized (Step S101), electrodes are formed (Step S102), and a peripheral component constituting thermoelectric conversion modules, such as a high thermal conductivity insulation member, is produced (Step S103). Those are arranged and formed to have the configuration illustrated in FIG. 1 to FIG. 3 (Step S104). Thereafter, the thermoelectric conversion modules, each of which contains the thermoelectric conversion material having a thickness which is determined based on a temperature difference between the pipes at the corresponding position, are provided between the pipes of liquid media (such as hot water and cold water) and are bonded to the pipes so as not to lose thermal conductivity to the thermoelectric conversion modules from the pipes (Step S105). Finally, the thermoelectric conversion modules and the liquid medium pipes are vacuum-packed, and thus the thermoelectric conversion unit is completed (Step S106).

The thermoelectric conversion unit was produced with the above method, and, as a result, output of 500 W/m² could be obtained and output could be increased by 50% or more, as compared to conventional methods.

In the above description, according to this example, even in the case where the temperature of the heat source is changed in the thermoelectric conversion unit and the plurality of thermoelectric conversion modules constituting the thermoelectric conversion unit have different temperature differences between the heat source and the cooling source, it is possible to provide a thermoelectric conversion unit capable of generating power with high thermoelectric conversion efficiency.

### Example 2

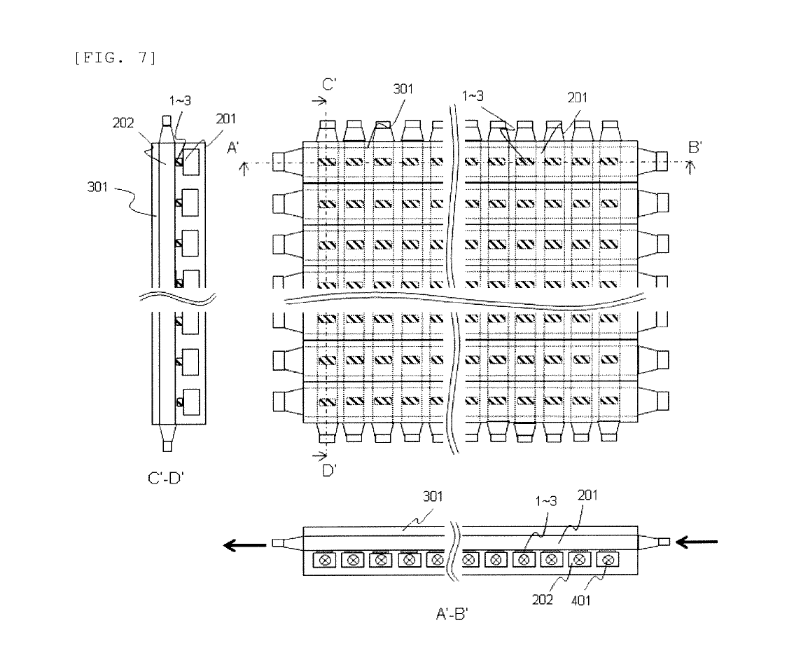

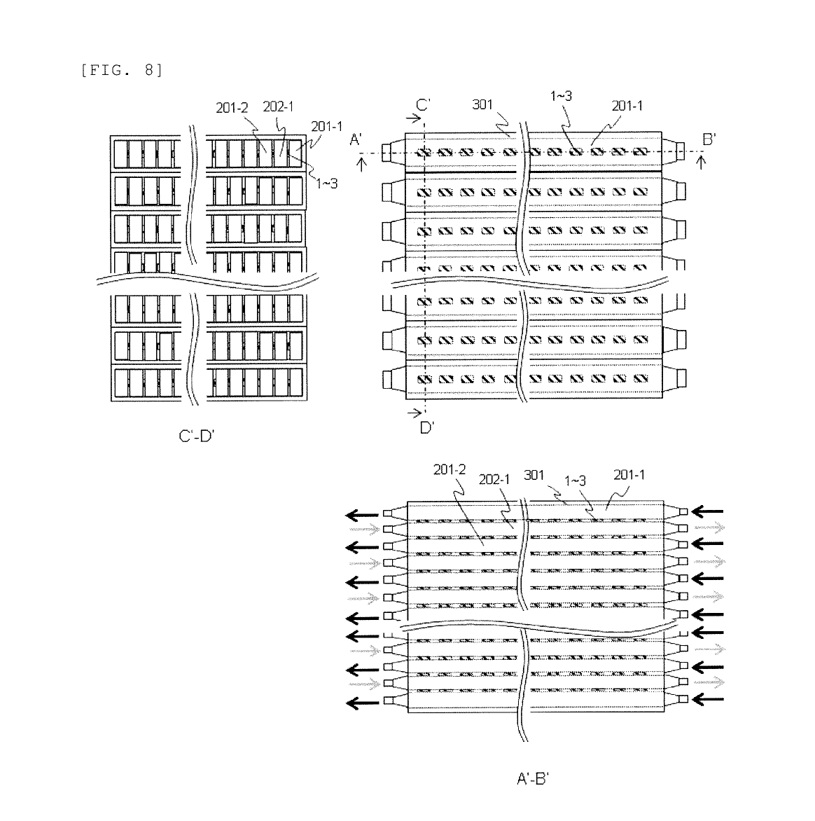

Example 2 of the invention will be described with reference to FIG. 6 and FIG. 7. Note that matters which have been described in Example 1 but are not described in this example are applicable to this example, unless otherwise noted.

FIG. 6 illustrates a configuration example of a thermoelectric conversion unit having a structure in which the plurality of thermoelectric conversion units described in Example 1, in each of which the plurality of thermoelectric conversion modules are interposed between the pair of hot water/cold water pipes, are arranged substantially in parallel on a plane surface. An upper right view of FIG. 6 is a top view, a lower right view of FIG. 6 is a cross-sectional view taken along the line A′-B′, and a left view of FIG. 6 is a cross-sectional view taken along the line C′-D′. Hot water and cold water are separated and enter the hot water pipe and the cold water pipe, respectively. As indicated by an arrow in the A′-B′ cross-sectional view, hot water and cold water enter the pipes so as to flow in opposite directions. With this, a temperature difference gradient is small, as compared with a case where hot water and cold water flow in the same direction, and therefore it is possible to achieve a thermoelectric conversion unit having higher output. Further, with this structure, it is possible to easily attach the thermoelectric conversion unit in a place where a plane-shaped space can be provided, and it is possible to obtain electric power corresponding to the number of thermoelectric conversion units.

Unlike the thermoelectric conversion unit illustrated in FIG. 6, FIG. 7 illustrates a thermoelectric conversion unit having a structure in which hot water and cold water can enter pipes so as to flow in a direction in which flow of hot water and flow of cold water are substantially orthogonal to each other. An upper right view of FIG. 7 is a top view, a lower right view of FIG. 7 is a cross-sectional view taken along the line A′-B′, and a left view of FIG. 7 is a cross-sectional view taken along the line C′-D′. The hot water pipes 201 and the cold water pipes 202 are arranged to be orthogonal to each other, and the thermoelectric conversion modules (1 to 3) are arranged in points of intersection thereof. In the case where flow of hot water is set as indicated by an arrow in the A′-B′ cross-sectional view, cold water flows in a direction of 401 or in an opposite direction thereof. With this, temperature differences generated in the individual thermoelectric conversion modules are larger than those in the configuration example illustrated in FIG. 6, and therefore it is possible to provide a thermoelectric conversion unit having higher output.

The thermoelectric conversion unit having the configurations illustrated in FIG. 6 and FIG. 7 was produced, and, as a result, output of 600 W/m² or more could be obtained and output could be increased by 50% or more, as compared to conventional methods.

In the above description, according to this example, even in the case where the temperature of the heat source is changed in the thermoelectric conversion unit and the plurality of thermoelectric conversion modules constituting the thermoelectric conversion unit have different temperature differences between the heat source and the cooling source, it is possible to provide a thermoelectric conversion unit capable of generating power with high thermoelectric conversion efficiency.

### Example 3

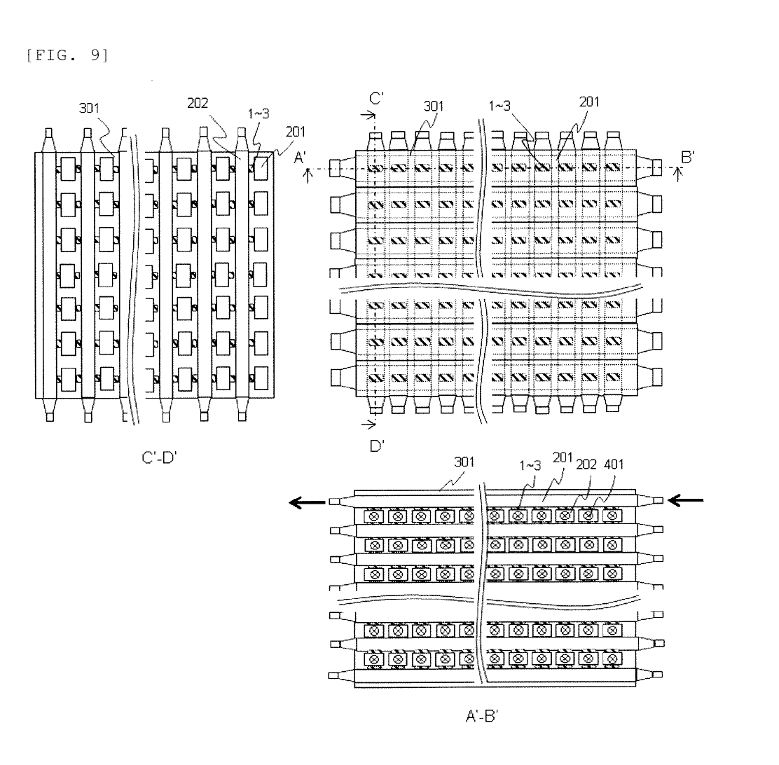

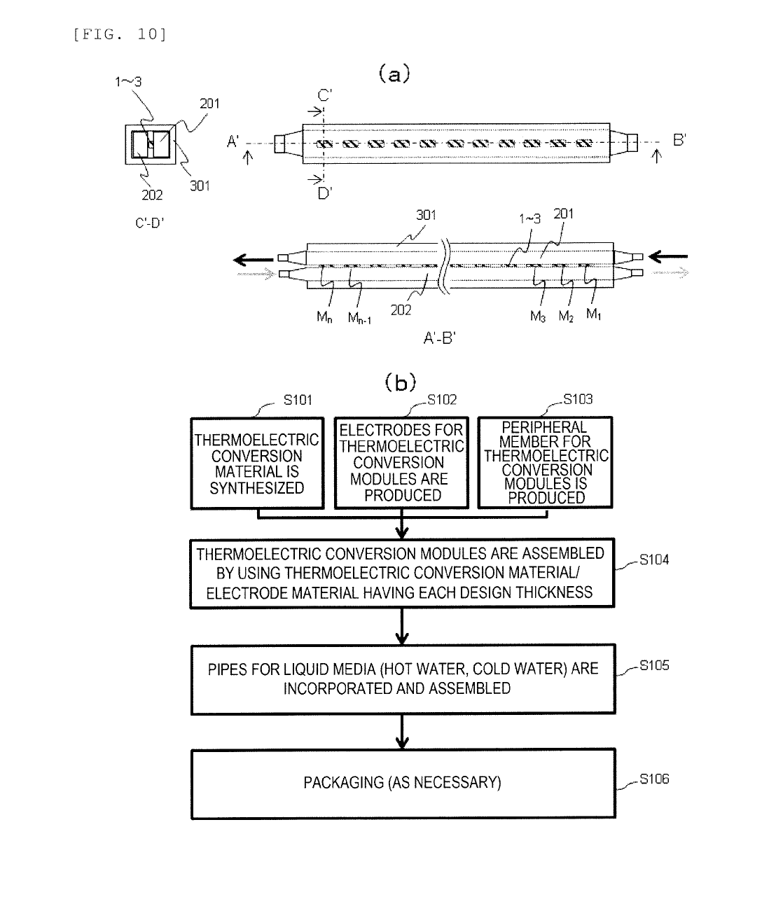

Example 3 of the invention will be described with reference to FIG. 8 and FIG. 9. Note that matters which have been described in Example 1 but are not described in this example are applicable to this example, unless otherwise noted.

FIG. 8 illustrates a configuration example of a thermoelectric conversion unit having a structure in which the hot water pipes 201 and the cold water pipes 202 are stacked in vertical and horizontal directions so as to be substantially in parallel and the thermoelectric conversion modules (1 to 3) are arranged between the pipes. An upper right view of FIG. 8 is a top view, a lower right view of FIG. 8 is a cross-sectional view taken along the line A′B′, and a left view of FIG. 8 is a cross-sectional view taken along the line C′D′. As illustrated in the A′-B′ cross-sectional view or the C′-D′ cross-sectional view, the hot water pipes and the cold water pipes are alternately arranged in the vertical and horizontal directions, i.e., a hot water pipe (201-1)—a cold water pipe (202-1)—a hot water pipe (201-2)— . . . are arranged in this order. In this example, as indicated by an arrow in the cross-sectional view taken along the line A′-B′, hot water and cold water enter the pipes so as to flow in opposite directions. The thermoelectric conversion unit of this example is covered with the thermal insulation member 301. With this, thermal diffusion to the atmosphere from the hot water pipes 201 and the cold water pipes 202 is suppressed, and therefore it is possible to achieve a stable heat source and a stable cooling source.

Unlike a thermoelectric conversion unit 8 illustrated in FIG. 8, FIG. 9 illustrates a thermoelectric conversion unit having a structure in which hot water and cold water can enter pipes so as to flow in a direction in which flow of hot water and flow of cold water are substantially orthogonal to each other. An upper right view of FIG. 9 is a top view, a lower right view of FIG. 9 is a cross-sectional view taken along the line A′B′, and a left view of FIG. 9 is a cross-sectional view taken along the line C′D′. The hot water pipes 201 and the cold water pipes 202 are arranged to be orthogonal to each other, and the thermoelectric conversion modules (1 to 3) are arranged in points of intersection thereof. In the case where flow of hot water is set as indicated by an arrow in the A′-B′ cross-sectional view, cold water flows in a direction of 401 or in an opposite direction thereof. With this, temperature differences generated in the individual thermoelectric conversion modules are larger than those in the configuration example illustrated in FIG. 8, and therefore it is possible to provide a thermoelectric conversion unit having higher output. Further, a thermoelectric conversion unit 9 of this example is covered with the thermal insulation member 301. With this, thermal diffusion to the atmosphere from the hot water pipes 201 and the cold water pipes 202 is suppressed, and therefore it is possible to achieve a stable heat source and a stable cooling source.

The thermoelectric conversion unit having the configurations illustrated in FIG. 6 and FIG. 7 was produced, and, as a result, output of 600 W/m² or more could be obtained and output could be increased by 50% or more, as compared to conventional methods.

In the above description, according to this example, even in the case where the temperature of the heat source is changed in the thermoelectric conversion unit and the plurality of thermoelectric conversion modules constituting the thermoelectric conversion unit have different temperature differences between the heat source and the cooling source, it is possible to provide a thermoelectric conversion unit capable of generating power with high thermoelectric conversion efficiency.

Note that the invention is not limited to the above examples and includes various modification examples. For example, the above examples have been described in detail to easily understand the invention, and therefore the invention is not necessarily limited to the examples having all the configurations described above. Further, a part of a configuration of a certain example can be replaced with a configuration of another example, and a configuration of another example can be added to a configuration of a certain example. Further, another configuration can be added to, removed from, or replaced with a part of the configuration of each example.

### REFERENCE SIGNS LIST

1 . . . thermoelectric conversion module, 2 . . . thermoelectric conversion module, 3 . . . thermoelectric conversion module, 101 . . . p-type thermoelectric conversion material, 102 . . . n-type thermoelectric conversion material, 103 . . . p-type thermoelectric conversion material, 104 . . . n-type thermoelectric conversion material, 111 . . . electrode, 112 . . . electrode, 113 . . . electrode, 114 . . . electrode, 116 . . . electrode, 121 . . . high thermal conductivity insulation member, 122 . . . high thermal conductivity insulation member, 131 . . . package, 132 . . . thermoelectric conversion module end electrode, 133 . . . extraction wire, 201, 201-1, 201-2 . . . hot water pipe, 202, 202-1 . . . cold water pipe, 301 . . . thermal insulation member, 401 . . . hot water/cold water flow direction

1. A thermoelectric conversion unit, comprising:
a plurality of thermoelectric conversion modules including a plurality of pairs of n-type thermoelectric conversion material portions and p-type thermoelectric conversion material portions connected by electrodes for extracting electric power; and
supply means provided in upper and lower surfaces in a thickness direction of the n-type and p-type thermoelectric conversion material portions of the thermoelectric conversion modules, the supply means being for generating a temperature difference in the thermoelectric conversion modules and supplying a heat source and a cooling source for generating power by using a Seebeck effect of the thermoelectric conversion material portions, wherein:
the plurality of thermoelectric conversion modules are connected in parallel; and
one of the adjacent thermoelectric conversion modules or at least one of the plurality of thermoelectric conversion modules is different from another thermoelectric conversion module in at least one of a thickness of the thermoelectric conversion material portions, the kind of thermoelectric conversion material, and a thickness of the electrodes.

2. The thermoelectric conversion unit according to claim 1, wherein
a high thermal conductivity insulation member is arranged between the electrodes constituting the thermoelectric conversion modules and the heat source.

3. The thermoelectric conversion unit according to claim 1, wherein
the thermoelectric conversion modules are confidentially packaged by vacuum sealing.

4. The thermoelectric conversion unit according to claim 1, wherein
the means for supplying the heat source and the cooling source includes pipes through which respective liquid media flow and is arranged to be adjacent to the plurality of thermoelectric conversion modules.

5. The thermoelectric conversion unit according to claim 4, wherein
the pipes are arranged so that flow of a hot liquid medium and flow of a cold liquid medium are substantially in parallel with each other or substantially orthogonal to each other.

6. The thermoelectric conversion unit according to claim 1, wherein:
the thermoelectric conversion material portions are a Heusler alloy;
the Heusler alloy contains Fe, an element X, and an element Y;
the element X is at least one of the group consisting of Ti, Zr, Hf, V, Nb, Ta, Cr, Mo, W, Sc, and Y; and
the element Y is at least one of the group consisting of Si, Ge, Sn, Al, Ga, In, Zn, Cd, Hg, Ca, Sr, Ba, P, As, Sb, and Bi.

7. The thermoelectric conversion unit according to claim 6, wherein
the Heusler alloy has a crystal grain size of 1 μm or less.

8. A thermoelectric conversion unit, comprising:
a plurality of thermoelectric conversion modules including a plurality of pairs of n-type thermoelectric conversion material portions and p-type thermoelectric conversion material portions connected by electrodes for extracting electric power; and
supply means provided in upper and lower surfaces in a thickness direction of the n-type and p-type thermoelectric conversion material portions of the thermoelectric conversion modules, the supply means being for generating a temperature difference in the thermoelectric conversion modules and supplying a heat source and a cooling source for generating power by using a Seebeck effect of the thermoelectric conversion material portions, wherein:
the plurality of thermoelectric conversion modules are connected in parallel;
one of the adjacent thermoelectric conversion modules or at least one of the plurality of thermoelectric conversion modules is different from another thermoelectric conversion module in at least one of a thickness of the thermoelectric conversion material portions, the kind of thermoelectric conversion material, and a thickness of the electrodes;
αₕ=Aₕv
α_{c}=A_{c}v
where Tₕ represents a temperature of the heat source, T_{c} represents a temperature of the cooling source, κ represents thermal conductivity of the thermoelectric conversion material portion, m₀ represents a material property constant of the thermoelectric conversion material portion, αₕ represents a heat transfer coefficient of the heat source, α_{c} represents a heat transfer coefficient of the cooling source, v represents flow velocity of hot water and cold water, and Aₕ and A_{c} represent specific constants of temperature dependence of the heat source and the cooling source represent; and
a thickness t which satisfies
500 W/m²≧[(Tₕ−T_{c})2/{(1/αₕ)+(t/κ)+(1/α_{c})}]×[(m₀−1)/{m₀(Tₕ+273)+(T_{c}+273)}]
is selected as a thickness t of the thermoelectric conversion material portion.

9. The thermoelectric conversion unit according to claim 8, wherein
a high thermal conductivity insulation member is arranged between the electrodes constituting the thermoelectric conversion modules and the heat source.

10. The thermoelectric conversion unit according to claim 8, wherein
the thermoelectric conversion modules are confidentially packaged by vacuum sealing.

11. The thermoelectric conversion unit according to claim 8, wherein
the means for supplying the heat source and the cooling source includes pipes through which respective liquid media flow and is arranged to be adjacent to the plurality of thermoelectric conversion modules.

12. The thermoelectric conversion unit according to claim 11, wherein
the pipes are arranged so that flow of a hot liquid medium and flow of a cold liquid medium are substantially in parallel with each other or substantially orthogonal to each other.

13. The thermoelectric conversion unit according to claim 8, wherein:
the thermoelectric conversion material portions are a Heusler alloy;
the Heusler alloy contains Fe, an element X, and an element Y;
the element X is at least one of the group consisting of Ti, Zr, Hf, V, Nb, Ta, Cr, Mo, W, Sc, and Y; and
the element Y is at least one of the group consisting of Si, Ge, Sn, Al, Ga, In, Zn, Cd, Hg, Ca, Sr, Ba, P, As, Sb, and Bi.

14. The thermoelectric conversion unit according to claim 13, wherein
the Heusler alloy has a crystal grain size of 1 μm or less.

15. The thermoelectric conversion unit according to claim 8, wherein
even in the case where the thermoelectric conversion material portions have different thicknesses, the plurality of thermoelectric conversion modules are produced so as to have the substantially same thickness.
